(19) United States
(12) Patent Application Publication
(10) Pub. No.: US 2007/0279259 A1
(43) Pub. Date: Dec. 6, 2007

(54) Verification coverage extraction circuit and method, semiconductor device and emulation system

(75) Inventor: Kouji Hijikuro, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/798,810

(22) Filed: May 17, 2007

(30) Foreign Application Priority Data
May 22, 2006 (JP) 2006-141527

(51) Int. Cl. H03M 7/00

(52) U.S. Cl. 341/50

(57) ABSTRACT

Disclosed is a verification coverage extraction circuit for extracting the verification coverage rate at the time of circuit verification employing an emulation device, in which a state of the current cycle and a state of the next cycle of a state machine are coupled by a data coupling circuit into an item of data, this data is compressed to a data width which is a necessary minimum to express state transition by an encoder circuit, the state transition information is stored in a memory, with an output of the encoder circuit as an address, and the verification coverage information at the time of functional verification of a circuit under verification is extracted from the memory.

### FIELD OF THE INVENTION

This invention relates to a technique for verification of semiconductor devices. More particularly, this invention relates to a method and a circuit for extracting functional verification coverage of a circuit under verification, among a variety of circuits arranged in a semiconductor device, and to an emulation system.

### BACKGROUND OF THE INVENTION

With recent improvement in the semiconductor technology, the number of gates that may be formed on a system LSI (Large Scale Integration) is increased, such that a semiconductor integrated circuit of highly advanced multiple functions may be implemented on a single chip.

If a circuit of highly advanced multiple functions is to be implemented on a single chip, functional verification is crucial. The reason is that if functional verification is not thoroughly executed and functional defects are found after prototyping of a system LSI, the modification thereof requires expensive cost. In order to prevent such defects in the system LSI, a number of test patterns necessary for functional verification of semiconductor integrated circuits are provided to carry out HDL (Hardware Description language) simulation. However, as the circuit scale is increased, it is becoming increasingly difficult to evaluate to which extent faults present in the semiconductor integrated circuit can be detected with the test patterns used.

To solve this problem, such a simulation technique has been proposed in which the coverage is calculated at the time of execution of the HDL simulation, and in which evaluation is made on to which extent the semiconductor integrated circuit is operating with the test patterns used, in order to achieve a preset coverage (see Patent Document 1).

On the other hand, the HDL simulator suffers from a problem that it is slow in the execution speed, such that, if the large amount of information is to be processed as in the case of integrated circuits for audio or video processing of recent days, sufficient verification cannot be executed within a limited time until product development. To cope with this problem, and to enable the operation execution faster than with the HDL simulator, emulating the operation of the system LSI with a prototype board employing an electrically reprogrammable LSI including an FPGA (Field programmable Gate Array), by way of verification, has come to be used.

A typical configuration of an emulation system is now described. FIG. 2 is a diagram illustrating the configuration of an emulation system in its entirety. An emulation device 200 includes an FPGA 202 and is connected to a host computer 201. Within the FPGA 202, a wide variety of circuits may be implemented with use of external programs.

In carrying out the emulation, a circuit under verification 203 is mounted on the FPGA 202, and is operated as it is supplied with a test pattern 204 from the host computer 201. The host computer 201 receives results of verification 205 to verify whether or not the circuit operation is correct.

However, with the emulation employing the prototype board, it is difficult to calculate the coverage of a semiconductor integrated circuit which is among a variety of circuits for verification that may be dealt with by the HDL simulator.

By way of introducing the technique for helping comprehend the operational contents of the semiconductor integrated circuits, the Patent Document 2, for example, proposes a semiconductor device in which state transitions by a state transition control mechanism may be evaluated and analyzed with ease. This Patent Document 2 discloses a semiconductor device including a state code register, a state transition logic means, an expected value register and a comparator. The state code register holds state codes. The state transition logic means is supplied with a command specifying a desired state, and with the state codes, and determines the state code of an internal state, transition is to be made to next, to store the so determined state code in a state code register. The expected value register holds a state code, desired to be detected, as an expected value. The comparator compares the state code in the state code register to the expected value in the expected value register and outputs a coincidence signal on coincidence of the two signals. However, the Patent Document 2 neither discloses nor suggests extraction of the circuit verification coverage.

### [Patent Document 1]

Japanese Patent Kokai Publication No. JP-P2004-54549A

### [Patent Document 2]

Japanese Patent Kokai Publication No. JP-P2004-234720A

### SUMMARY OF THE DISCLOSURE

After all, the technology disclosed in Patent Document 1 is premised on simulation, and cannot be used on an emulation device. That is, in an HDL simulator, the circuit under verification is supervised on the HDL simulator and the operation of the circuit under verification in its entirety is controlled on the HDL simulator. Thus, when the test patterns are executed, the operation site in the circuit may be supervised in their entirety within the HDL simulator, thus allowing for facilitated coverage extraction. However, in case the circuit under verification is operated on an emulation device, the circuit operation of the circuit under verification in its entirety cannot be supervised on a host computer.

In the emulation device, the circuits to be verified are being operated in their entirety on a chip, the circuit operations cannot be known from the host computer

Thus, it becomes necessary to provide the circuit under verification with additional circuits for extracting verification coverage.

The above mentioned Patent Document 2 is designed to determine an expected value for the expected state transition. In case an expected value decision for the expected state transition is carried out, it may be known whether or not the state transition desired has been carried out. However, it may not be known which functions in the circuit have been carried out by the test pattern.

To comprehend the verification coverage of the circuit, it is necessary that the internal operations in the circuit be observed in their entirety from the host computer.

However, it is not practical to provide the circuit under verification with the additional circuits, because the resources that may be provided on the emulation device are limited and also because a huge amount of data communication with the host computer may be involved to disable high-speed verification which is a meritorious point of using the emulation device. Thus, such a scheme is needed in which circuit addition for extracting the verification coverage is suppressed to a necessary minimum and in which it is still possible to suppress reduction in the speed of verification otherwise caused by data communication with the host computer.

That is, in circuit verification by an emulation device, it is desired to implement a circuit for extracting the information on verification coverage, in which it is only sufficient to provide a lesser number of additional circuits and in which the speed of verification of the emulation device is not lowered in extracting the information on the verification coverage.

The invention disclosed by the present application may be summarized substantially as follows:

A verification coverage extraction circuit in one aspect of the present invention comprises: a memory; and a circuit unit that receives a state value of a current cycle of a state machine of said circuit under verification, and a state value of a next cycle thereof, at the time of functional verification of said circuit under verification and that writes a preset logic value in said memory, with paired bit data of said state value of the current cycle and said state value of the next cycle of said state machine or data derived from said bit data as address information; wherein in said memory state transition information of said circuit under verification is retained, thereby enabling extraction of the verification coverage information.

In the present invention, said circuit unit may comprise: a data coupling circuit that concatenates paired bit data of said state value of the current cycle and said state value of the next cycle of said state machine; and an encoder circuit that receives the concatenated data from said data coupling circuit, and compresses the concatenated data to data of a necessary minimum bit width to express the information of state transitions allowed in accordance with operational design parameters of said circuit under verification, said encoder circuit outputting the resulting compressed data to said memory as address information.

According to the present invention, the circuit under verification and the circuit for extraction of verification coverage may compose an emulation system.

A method in a further aspect of the present invention includes:

receiving a state value of a current cycle of a state machine of a circuit under verification, and a state value of a next cycle thereof, at the time of functional verification of said circuit under verification; and

writing a preset logic value in a memory, with paired bit data of said state of the current cycle and said state of the next cycle of said state machine or with data derived from said bit data as the address information; state transition information of said circuit under verification being retained in said memory, thereby enabling extraction of the verification coverage information.

The meritorious effects of the present invention are summarized as follows.

According to the present invention, the information on state transition of the state machine at the time of the end of verification may be obtained by adding the verification coverage extraction circuit to the circuit under verification. Thus, it becomes possible to measure the verification coverage at the time of circuit verification in the circuit operation verification by the emulation device.

Moreover, according to the present invention, the information on state transition of the circuit under verification may be saved in the memory within the verification coverage extraction circuit to diminish the volume of communication with the host computer at the time of functional verification to provide for shorter functional verification time.

In addition, according to the present invention, the circuit verification time may be shorter because verification coverage of the test pattern used may be known so that the test patterns may be selected and hence the test patterns with overlapped operations may be omitted. The result is the shorter circuit verification time.

Thus, according to the present invention, a smaller number of additional circuits suffice, in the circuit verification in the emulation device, with the result that the information on the verification coverage may be extracted without lowering the speed of verification of the emulation device.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of an example of the present invention.

FIG. 2 is a diagram showing the system configuration for circuit verification employing an emulation device.

FIG. 3 is a diagram showing the internal configuration of a circuit under verification 203 according to an example of the present invention.

FIG. 4 is a diagram showing the input data-output data connection relationships of a data coupling circuit of the example of the present invention.

FIG. 5A is a diagram showing a state transition diagram and FIG. 5B is a diagram showing the state of state transition in tabular form.

FIG. 6 is a diagram showing the memory connection relationships in the example of the present invention.

FIG. 7 is a timing chart for illustrating the operation of verification coverage extraction in the example of the present invention.

FIG. 8 is a flowchart for illustrating the processing for verification coverage extraction in the example of the present invention.

### EXEMPLARY EXAMPLES OF THE INVENTION

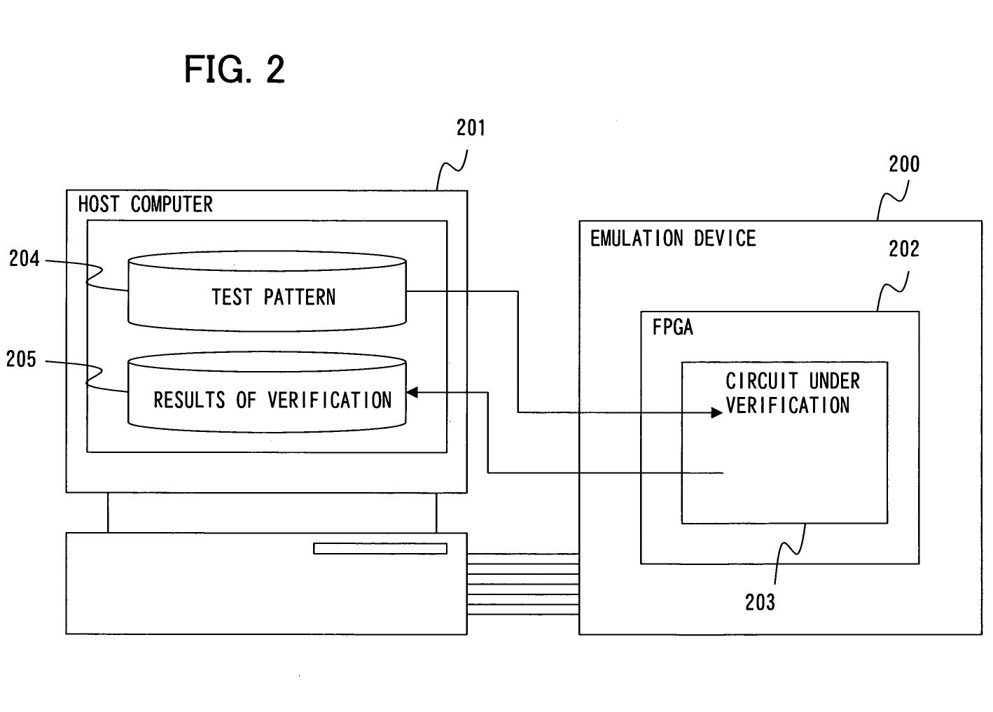

The present invention will now be described in further detail with reference to the accompanying drawings. The circuit for extracting verification coverage according to the present invention extracts the information on the functional verification coverage at the time of functional verification, and may be applied to an emulation system which has been described with reference to FIG. 2. That is, the circuit that extracts functional verification coverage, also termed the functional verification coverage extraction circuit, is annexed to a circuit under verification (203) of an FPGA (202) of the emulation device (200).

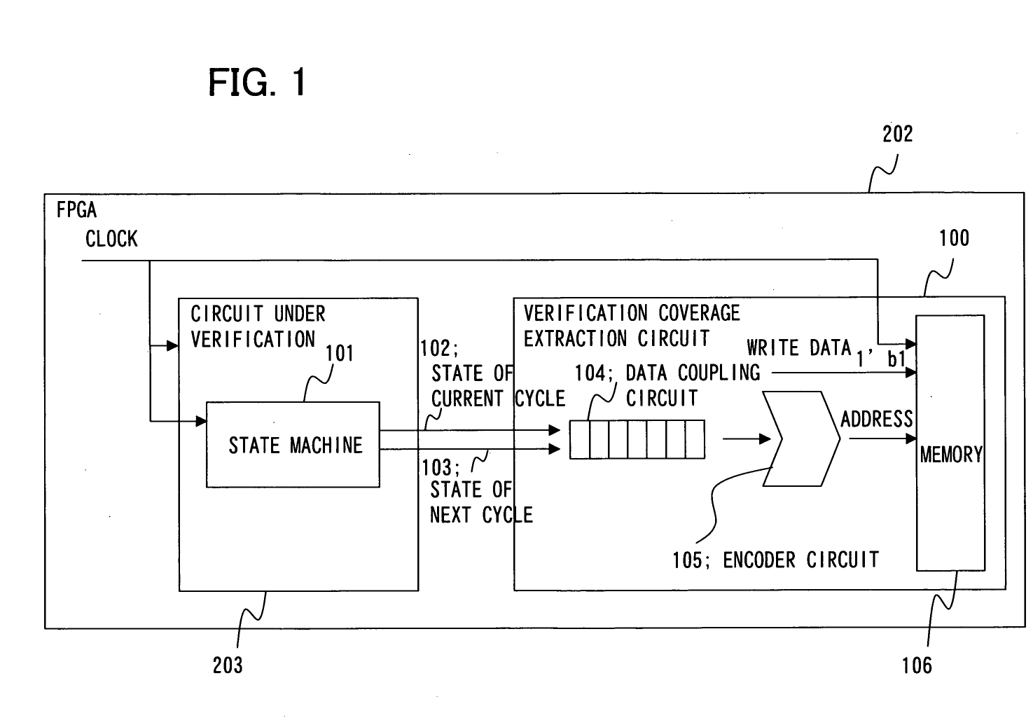

Referring to FIG. 1, the verification coverage extraction circuit (100), connected to the circuit under verification (203), includes a data coupling circuit (104), an encoder circuit (105) and a memory (106) for storage of the state transition information. The data coupling circuit couples two state values from a state machine (101) in the circuit under verification (203), that is, concatenates a state value of a current cycle (102) and a state value of a next cycle state (103). The encoder circuit receives the concatenated data from the data coupling circuit (104) to compress the received data to data of a required data width based on the circuit information. The memory receives the data signal output from the encoder circuit as an address signal and writes a 1-bit signal in synchronization with a clock signal used for operating the circuit under verification (203). According to the present invention, the information on circuit state transitions at the time of circuit verification may be extracted, by virtue of the circuit for coupling the state values without lowering the verification speed at the time of circuit operation verification employing an emulation device, and the state transition memory. In this manner, which states of the circuit have been operated by the test patterns used may be known to derive the information representing the circuit quality.

Moreover, according to the present invention, the limited resources for circuit implementation in the emulation device may be made smaller by virtue of the encoder circuit (105).

FIG. 1 shows the configuration of an emulation device according to a first example of the present invention. Referring to FIG. 1, an FPG 202 of an emulation device includes a circuit under verification 203 and a verification coverage extraction circuit 100, also termed a functional verification coverage extraction circuit. From results of verification 205 of the emulation system of FIG. 2, the verification coverage of the circuit in its entirety may not be known. Thus, in the present invention, a verification coverage extraction circuit 100 is added to the circuit under verification 203.

The circuit under verification 203 includes a state machine 101.

The verification coverage extraction circuit 100 includes a data coupling circuit 104, an encoder circuit 105 and a memory 106.

The information on a state of the current cycle 102. and the information on a state of the next cycle 103, in the state machine 101 in the inside of the circuit under verification 203, are taken to outside the circuit under verification 203. These two states are coupled to an item of data by the data coupling circuit 104 of the verification coverage extraction circuit 100. Meanwhile, the states 102 and 103 remain in the same states, or the state transitions to the state 103, based on a state transition diagram of the state machine 101 of the circuit under verification 203 operating in accordance with a test pattern supplied.

The data generated by the data coupling circuit 104 is compressed by the encoder circuit 105 so that the data will be represented in a unique value with the necessary minimum number of bits.

The memory 106 is configured such that a logic value (binary ‘1’) is written therein, with data output from the encoder circuit 105 as the address information.

The memory 106 is driven by a clock signal which is the same as the clock used for the circuit under verification 203.

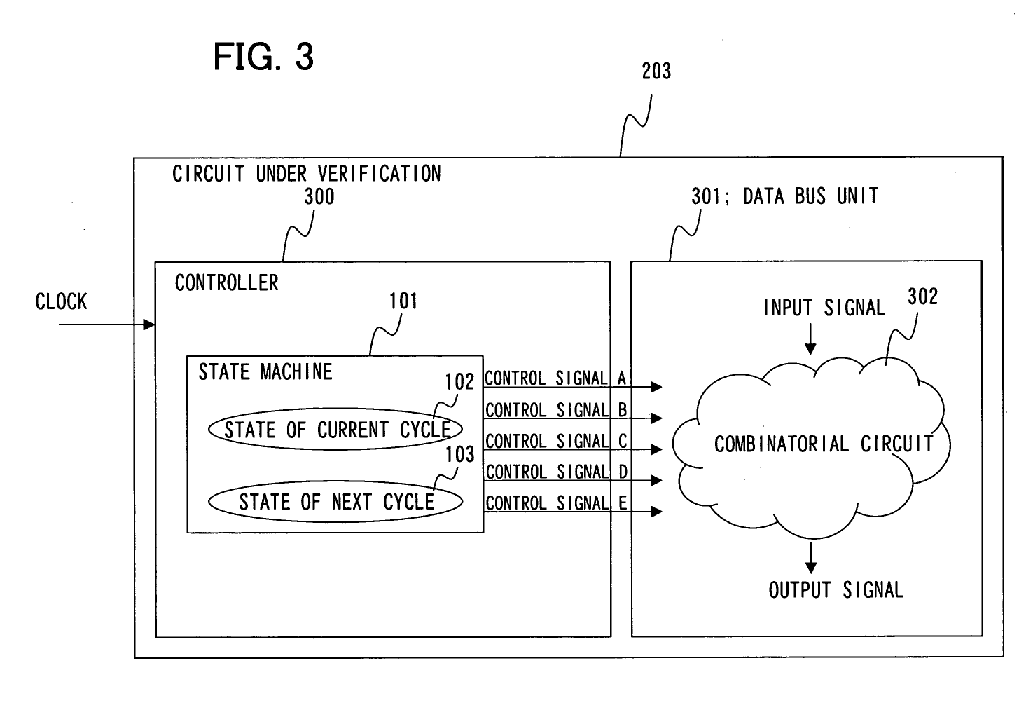

The configuration of the circuit under verification 203 and the state machine are now described in detail with reference to FIG. 3.

The circuit under verification 203 includes, in general, a control unit 300 and a data path unit 301, as shown in FIG. 3.

The control unit 300 includes the state machine 101. During the circuit operation, the state machine 101 holds values of the state of the current cycle 102 and the state of the next cycle 103.

The state of the next cycle 103 is determined by a signal supplied to the control unit 300.

The data path unit 301 is responsive to the control signal, as determined depending on the state of the current cycle 102 of the control unit 300, to determine the operation in a combination circuit 302 and an output signal.

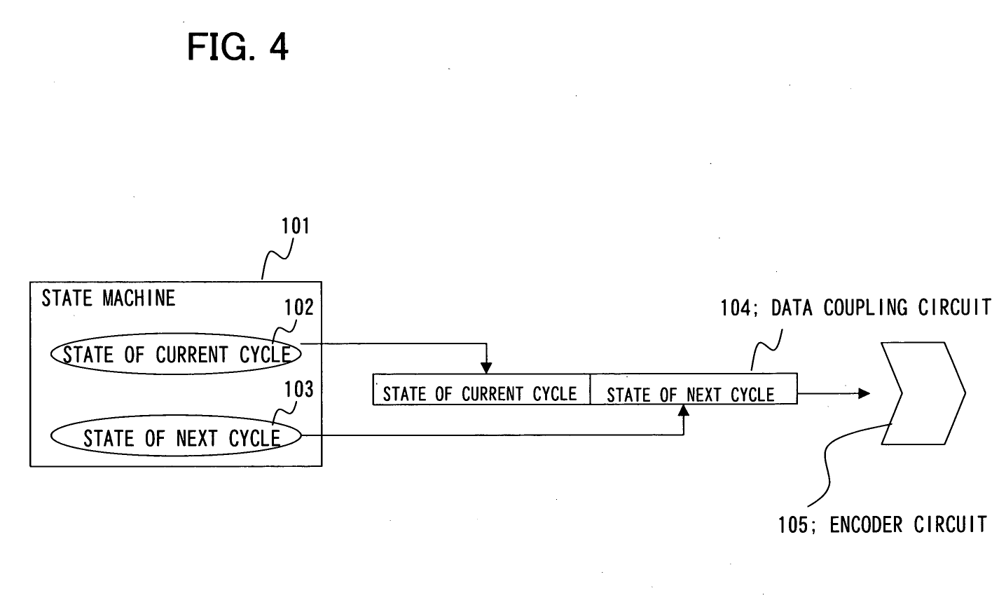

Referring to FIG. 4, the data coupling circuit 104, coupling the values of the state of the current cycle 102 and the state of the next cycle 103, as retained by the state machine 101, shown in FIG. 1, is now described in detail.

The data coupling circuit 104 couples the state of the current cycle 102 and the state of the next cycle 103 to send the so concatenated data over a data bus to an encoder circuit 105 in parallel.

The circuit parameters of the encoder circuit 105 are determined based on output data of the data coupling circuit 104 (bit data) and on the state transition information, which is derived from circuit parameters.

From the bus width, determined by the data coupling circuit 104, the encoder circuit 105 compresses the data from the data coupling circuit 104 into data, which represents the state transition information with a smaller bit width, to reduce the capacity of the memory 106 used for storing the verification coverage information.

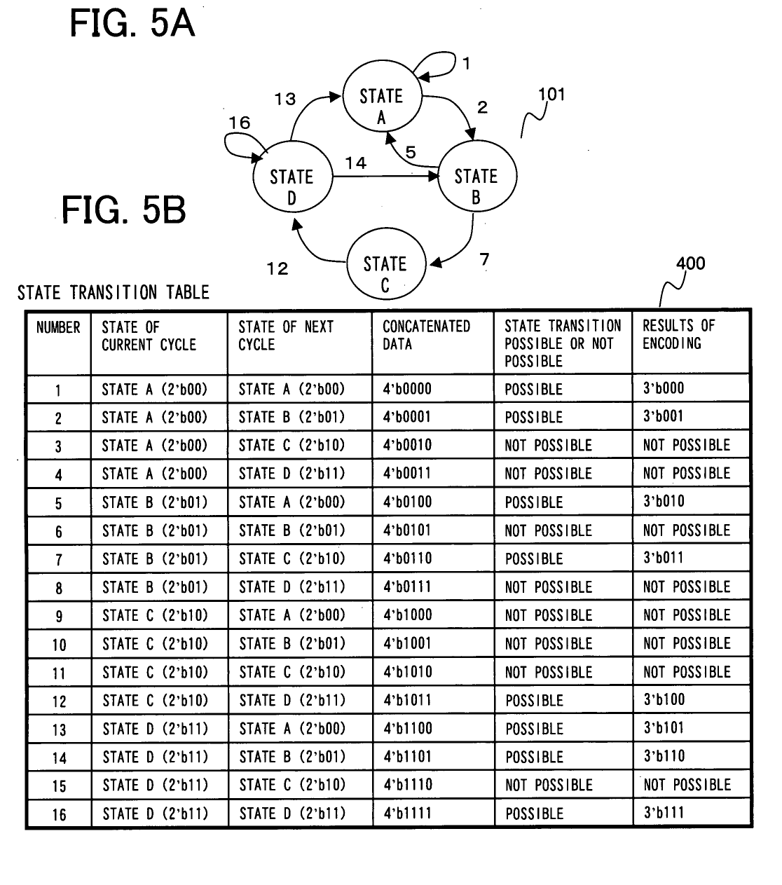

The compression of data width by the encoder circuit 105 is now described in detail with reference to FIGS. 5A and 5B. FIG. 5A is a state transition diagram and FIG. 5B shows a list of state transitions in a tabular format.

In FIG. 5A and 5B, the state machine 101 has four states, namely the states A to D.

A state transition diagram 400, shown in FIG. 5B, is now described.

Referring to the states of the cycles, output from the state machine 101, it is assumed that the state A is expressed, as hardware, by a binary number 00 (2′b00), the state B is expressed, as hardware, by a binary number 01 (2′b01), the state C is expressed, as hardware, by a binary number 10 (2′b10) and the state D is expressed, as hardware, by a binary number 11 (2′b11).

The state transition diagram shows, in a tabular form, the transition information of the state of the current cycle 102 and the state of the next cycle 103, data values of data concatenated by the data coupling circuit 104, and data obtained on compression by the encoder circuit 105, given the circuit parameters, to shortest possible data widths of only the concatenated data that allow for state transitions. If, in the state transition diagram of FIG. 5B, the state of the current cycle is the state A (binary number 00) and the state of the next cycle is the state B (binary number 01), the concatenated data, obtained by the data coupling circuit 104, may be represented as 4-bit binary number 0001 (4′b0001).

Given the operating circuit parameters, there are eight possible state transitions, namely
(a) from state A to state A;
(b) from state A to state B;
(c) from state B to state A;
(d) from state B to state C;
(e) from state C to state D;
(f) from state D to state A;
(g) from state D to state B; and
(h) from state D to state D
   as circuit state transitions. Therefore, each state transition may be represented by a three-bit hardware.

The encoder circuit 105 assigns unique values to respective state transitions to convert each of the concatenated data output from the data coupling circuit 104 into a unique value.

That is, in the state machine 101 of state transitions of FIG. 5A, the practically possible state transitions, out of 16 state transitions of numbers 1 to 16, in the state transition diagram 400 of FIG. 5B, are the state transitions of the Nos. 1, 2, 5, 7, 12, 13, 14 and 16. There can never be any other transitions.

Thus, the number of bits can be compressed by the encoder circuit 105, compressing the combinations of 2 bits for ‘the states of the current cycle 102’ and 2 bits for ‘the states of the next cycle 103’, totaling at 4 bits (the number of bits of the data coupling circuit 104), into combinations of three bits, that is, eight combinations.

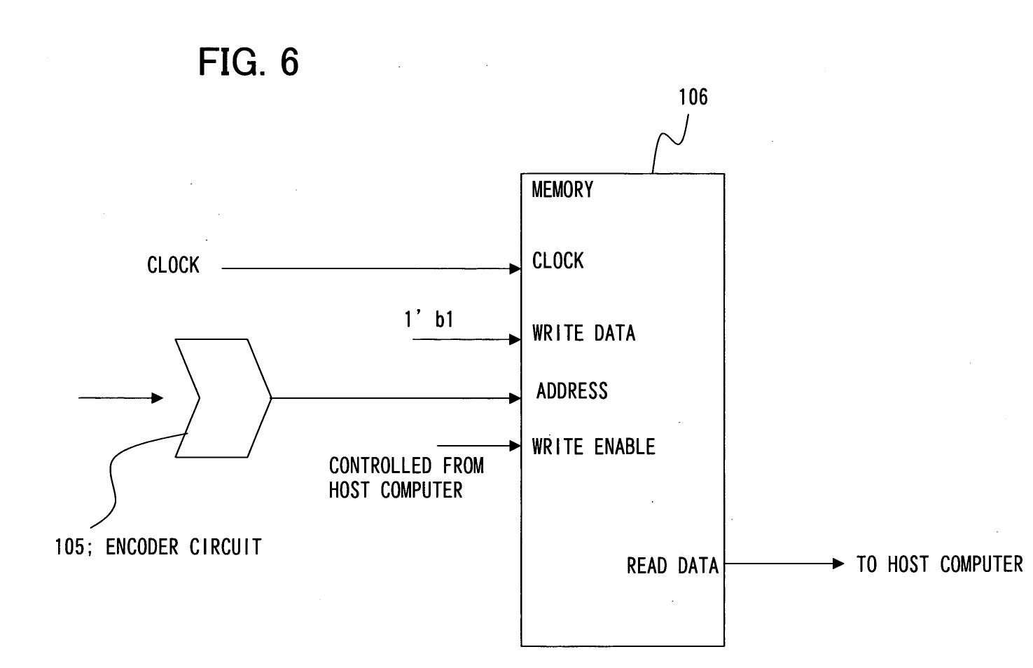

The memory 106 in which to save the results of verification coverage check is now described in detail with reference to FIG. 6. The memory 106 is of the memory constitution similar to a routine SRAM (Static Random Access Memory). On startup of verification, all values in the memory are set to 0.

The clock which is the same as the clock signal supplied to the circuit under verification 203 is supplied to the memory 106. ‘1’ is supplied at all times to a write data input of the memory 106. An output signal from the encoder circuit 105 is supplied to an address input of the memory 106. A write enable signal, which controls the writing in the memory 106, is controlled by a signal linked from the host computer (201 of FIG. 2).

In the above circuit configuration, the address written in the memory 106 is specified by a value output from the encoder circuit 105, and data ‘1’ is written in the so specified memory address.

The address where ‘1’ has been written indicates that address the state has transitioned to another state at the time of functional verification of the circuit under verification 203.

After the end of the verification, the value of the memory 106 is confirmed on a host computer (201 of FIG. 2) to identify the state transition that occurred at the time of the verification.

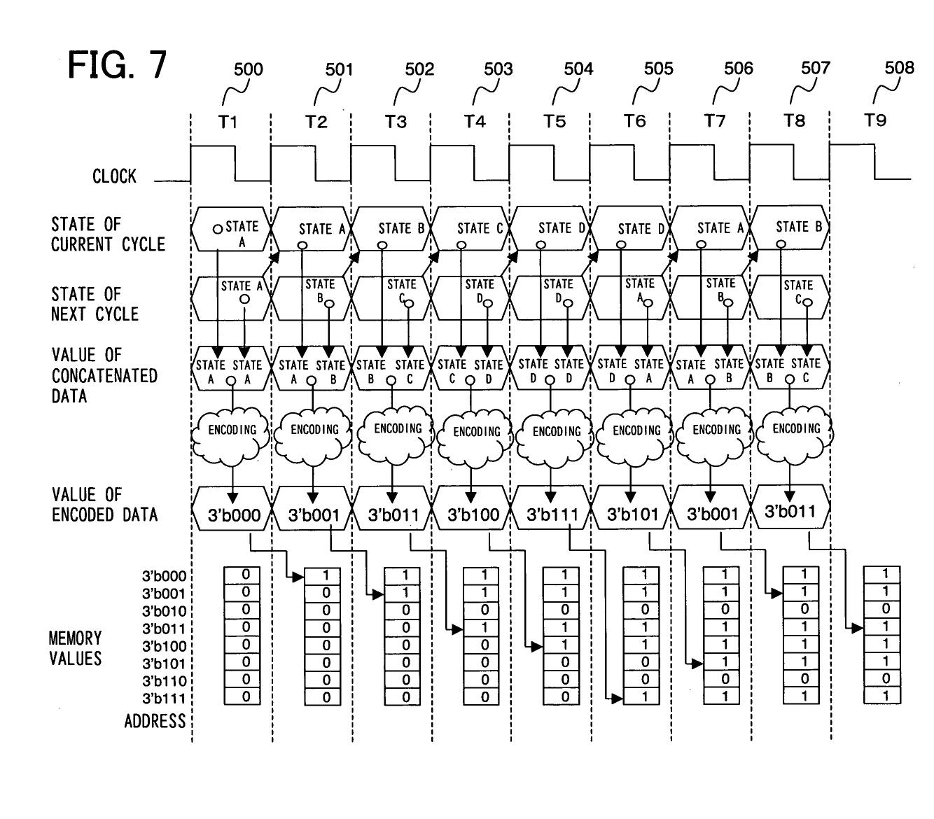

Referring to the timing chart of FIG. 7, the operation of the verification coverage extraction circuit 100 is now explained. FIG. 7 shows the current cycle states and the next cycle states of the state machine of the circuit under verification 203, operating in synchronization with the clock signal, the values of the concatenated data, the values of the encoded data, and the memory values. The circuit operation is based on the state transition diagram 400 of FIG. 5B, taken as an example.

In a cycle T1 (500), the current cycle state is a state A and the state of the next cycle is a state S. The state A, which is the state of the current cycle, and the state A, which is the state of the next cycle, are concatenated to one item of data by the data coupling circuit 104. This item of data is encoded by the encoder circuit 105 and the so encoded data is expressed as 3′b000. The contents of the memory 106 are all 0 at a cycle T1.

In a cycle T2 (501), the state A, which is the state of the next cycle to the cycle T1 (500), becomes the state of the current cycle of the cycle T2 (501). The state of the next cycle is newly determined. The concatenated data by the data coupling circuit 104 and the encoded data are generated in the same way as in the cycle T1 (500).

In the cycle T2, ‘1’ is written in a memory address 000, with the data of the value resulting from the encoding processing of the cycle T1 (500) as address. This value ‘1’ written in the memory 106 is retained until the memory 106 is cleared.

After execution of the cycles T3 (502) through to T9 (508), ‘1’ has been written in each of memory addresses indicated by the value of the encoding processing, while ‘0’ has been written in each of the memory addresses not indicated by the value of the encoding processing.

It is seen from the memory contents of FIG. 7 that, when the processing has advanced to a cycle T9 (508), transition has been made through six out of eight states, and that transition has not been made through two states.

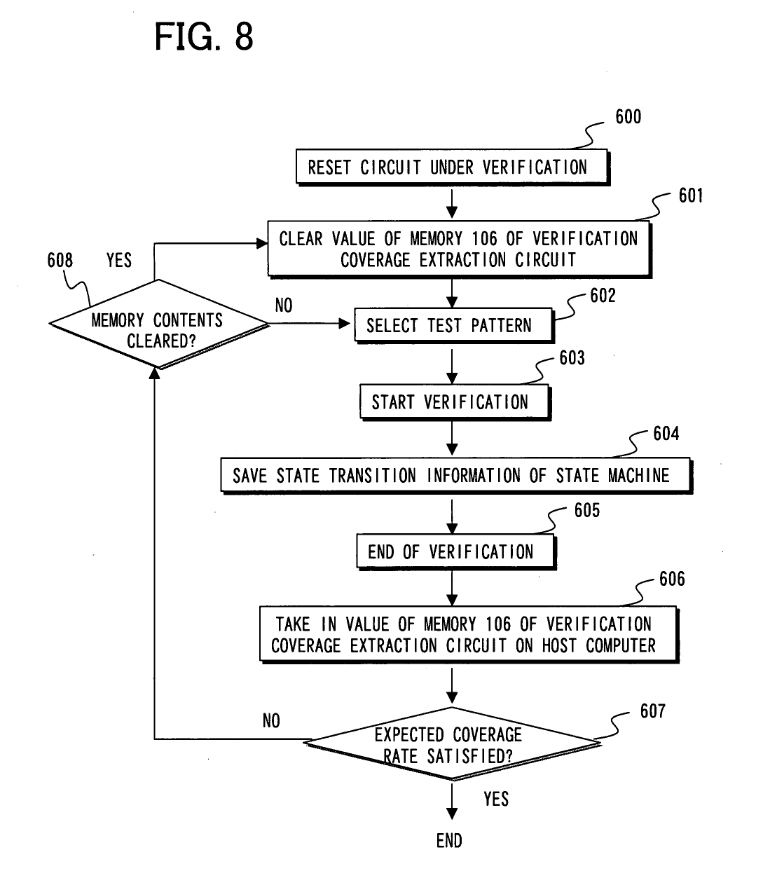

The verification coverage check flow is now described with reference to a flowchart of FIG. 8 which shows the processing flow from the start until the end of verification.

The circuit under verification 203 is reset and is caused to be in the ready state of verifying the internal circuit thereof. The state transitions of the state machine 101 in the circuit 203 are reset (step 600).

The contents of the memory 106 of the verification coverage extraction circuit 100 are cleared in preparation for receiving the state transition information of the state machine 101 (step 601).

A test pattern for performing the functional verification of the circuit under verification 203 is then prepared and provided (step 602).

The operation for verification is started (step 603) and subsequently brought to an end (step 605), during which the verification coverage extraction circuit 100 observes and stores the state transition information of the state machine 101 (step 604).

The contents of the memory 106 of the verification coverage extraction circuit 100 as of the end of verification are read by the host computer (201 of FIG. 2) (step 606).

It is checked from the read data whether or not the verification coverage as expected has been met (step 607).

If, as a result of check in the step 607, the verification coverage has been met (YES branch of step 607), the processing for verification coverage check comes to a close. If the verification coverage has not been met (NO branch of step 607), functional verification is again carried out, using a new test pattern. If the functional verification is again carried out, it is checked whether or not the contents of the memory 106 are to be cleared (step 608). If the contents of the memory 106 are to be cleared (YES branch of step 608), processing reverts to and re-starts at the processing to clear the contents of the memory 106 of the verification coverage extraction circuit 100 (step 601). If the contents of the memory 106 are not to be cleared (NO branch of step 608), a test pattern is selected (step 602) to repeat the processing.

The operation as well as the meritorious effect of the present example is now described.

In carrying out functional verification of a circuit on an emulation device, a verification coverage extraction circuit is annexed to the circuit under verification to extract the state information of the state machine within the circuit under verification.

Since the verification coverage extraction circuit is provided within the semiconductor device, the functional verification coverage can be extracted without lowering the speed of functional verification.

Since the contents of the inner operations of the state machine in the circuit device may be known from one test pattern used to another, those test patterns needed for achieving the targeted verification coverage may be selected to provide for shorter verification time.

Since the state transition not covered by the test pattern used may be known, it becomes possible to improve the quality of the circuit operation.

In the above-described example, an exemplary constitution in which the verification coverage extraction circuit is provided within the FPGA has been described. However, the present invention is not limited to this configuration and the verification coverage extraction circuit may also be provided within a semiconductor integrated circuit device (LSI) as a final product. In the above example, output bit data of a 4-bit width of the data coupling circuit 104 is compressed by the encoder circuit 105 into three-bit data used as an address signal for the memory 106. It is to be noted that the present invention is not limited to this configuration. If it is unnecessary to make the most efficient use of the memory capacity, the output bit data of 4-bit widths of the data coupling circuit 104 may directly be used as an address signal. On the other hand, the signal outputs of the state of the current cycle 102 and the state of the next cycle 103 from the circuit under verification 203 are parallel outputs in FIG. 1. However, the present invention is not to be limited to this constitution.

Although the present invention has so far been described with reference to preferred examples, the present invention is not to be restricted to the examples. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A verification coverage extraction circuit for extracting verification coverage information of a circuit under verification, comprising:
a memory; and
a circuit unit that receives a state value of a current cycle of a state machine of said circuit under verification, and a state value of a next cycle thereof, at the time of functional verification of said circuit under verification and that writes a preset logic value in said memory, with paired bit data of said state value of the current cycle and said state value of the next cycle of said state machine or data derived from said bit data as address information; wherein in said memory state transition information of said circuit under verification is retained.

2. The verification coverage extraction circuit according to claim 1, wherein said circuit unit comprises:
a data coupling circuit that concatenates paired bit data of said state value of the current cycle and said state value of the next cycle of said state machine; and
an encoder circuit that receives the concatenated data from said data coupling circuit, and compresses the concatenated data to data of a necessary minimum bit width to express the information of state transitions allowed in accordance with operational design parameters of said circuit under verification, said encoder circuit outputting the resulting compressed data to said memory as the address information.

3. The verification coverage extraction circuit according to claim 1, wherein said circuit under verification and said verification coverage extraction circuit compose an emulation device.

4. A semiconductor device having a verification coverage extraction circuit set forth in claim 1.

5. The verification coverage extraction circuit according to claim 2, wherein said data coupling circuit receives state values of the current cycle and the next cycle of the state machine of said circuit under verification, arranged within an electrically reprogrammable semiconductor device mounted on an evaluation substrate, concatenates the state values of the current and next cycles of said state machine and outputs resulting concatenated data; and
said memory retains a first logic value with said encoded data output from said encoder circuit as an address.

6. The verification coverage extraction circuit according to claim 5, wherein said circuit under verification includes a control unit and a data path unit that receives a control signal from said control unit;
said control unit including said state machine;
said circuit under verification outputting the states of the current cycle and the next cycle of said state machine.

7. The verification coverage extraction circuit according to claim 5, wherein said data coupling circuit includes a combination circuit that couples the states of the current cycle and the next cycle retained within said state machine to output concatenated cycle states as a data representation.

8. The verification coverage extraction circuit according to claim 5, wherein said memory receives data output from said encoder circuit as an address and also receives a signal of a level corresponding to a first logic value as write data;
said memory is driven linked with said circuit under verification; and
said memory receives a write enable signal from a host computer which is connected to an emulation device including said verification coverage extraction circuit;
read data from said memory being transferred to said host computer.

9. The verification coverage extraction circuit according to claim 5, wherein a second logic value is written in said memory at the time of resetting.

10. An emulation system comprising:
an emulation device having mounted a circuit under verification and a verification coverage extraction circuit set forth in claim 5, on a reprogrammable semiconductor device, and
a host computer connected to said emulation device.

11. A method for extracting verification coverage of a circuit under verification, said method comprising:
receiving a state value of a current cycle of a state machine of said circuit under verification, and a state value of a next cycle thereof, at the time of functional verification of said circuit under verification; and
writing a preset logic. value in a memory, with paired bit data of said state of the current cycle and said state of the next cycle of said state machine or with data derived from said bit data as the address information; the state transition information of said circuit under verification being retained in said memory.

12. The method according to claim 11, comprising:
concatenating a set of a state value of a current cycle of a state machine of said circuit under verification and a state value of a next cycle thereof to an item of data; and
writing a first logic value in a memory, with said data obtained by concatenation or with a data obtained on reducing the number of bits of said data by compression, as address information.
